(19) United States
(12) Patent Application Publication
(10) Pub. No.: US 2025/0333834 A1
(43) Pub. Date: Oct. 30, 2025

(54) DEPOSITION MASK

(71) Applicant: Samsung Display Co., LTD., Yongin-si (KR)

(72) Inventors: Jeong Kuk KIM, Yongin-si (KR); Ji Hyun JUNG, Yongin-si (KR); Sung Woon KIM, Yongin-si (KR); Sung Won CHO, Yongin-si (KR); Jun Ho JO, Yongin-si (KR)

(21) Appl. No.: 18/965,822

(22) Filed: Dec. 2, 2024

(30) Foreign Application Priority Data
Apr. 24, 2024 (KR) 10-2024-0054845

(51) Int. Cl. C23C 14/04; G02B 27/01; H10K 71/16

(52) U.S. Cl. CPC C23C 14/042; G02B 27/0172; H10K 59/1201; H10K 71/166; G02B 2027/0178

(57) ABSTRACT

A deposition mask includes a mask substrate including a cell area and a cell peripheral area; a mask membrane positioned in the cell area of the mask substrate and including a pixel opening and a mask shadow surrounding the pixel opening; a first upper inorganic layer positioned on the cell peripheral area of the mask substrate and including a first protrusion that protrudes more toward the cell area than a side surface of the mask substrate; and a second upper inorganic layer positioned on the first upper inorganic layer and including a second protrusion that protrudes more toward the cell area than the side surface of the mask substrate. The mask shadow includes a first mask shadow spaced apart from the first protrusion; and a second mask shadow spaced apart from the second protrusion.

This application claims priority to Korean Patent Application No. 10-2024-0054845, filed on Apr. 24, 2024, and all the benefits accruing therefrom under 35 U.S.C. § 119, the content of which in its entirety is herein incorporated by reference.

### BACKGROUND

### 1. Technical Field

The present disclosure relates to a deposition mask.

### 2. Description of the Related Art

Wearable devices have been developed in the form of glasses or a helmet and focuses on a distance close to the user's eyes. Examples of such wearable devices include a head mounted display (HMD) device or augmented reality (hereinafter, referred to as

“AR”) glass. Such wearable devices may provide a user with an AR screen or a virtual reality (hereinafter, referred to as “VR”) screen.

A wearable device such as, for example, the HMD device or the AR glass may be implemented according to a display specification of at least 2000 pixels per inch (PPI) to allow the user to use the device for a relatively long time without feeling dizzy. To this end, organic light emitting diode on silicon (OLEDoS) technology, which may provide a small organic light emitting display device with high resolution, is emerging. OLEDoS is a technology that disposes organic light emitting diodes (OLEDs) on a semiconductor wafer substrate on which a complementary metal oxide semiconductor (CMOS) is disposed.

### SUMMARY

Aspects of the present disclosure provide a silicon deposition mask supportive of manufacturing a high-resolution display panel.

Aspects of the present disclosure also provide a deposition mask with improved adhesion to the display panel.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

In an embodiment of the disclosure, a deposition mask includes a mask substrate including a cell area and a cell peripheral area; a mask membrane positioned in the cell area of the mask substrate and including a pixel opening and a mask shadow surrounding the pixel opening; a first upper inorganic layer positioned on the cell peripheral area of the mask substrate and including a first protrusion that protrudes more toward the cell area than a side surface of the mask substrate; and a second upper inorganic layer positioned on the first upper inorganic layer and including a second protrusion that protrudes more toward the cell area than the side surface of the mask substrate, wherein the mask shadow includes a first mask shadow spaced apart from the first protrusion with the pixel opening interposed between the first mask shadow and the first protrusion, wherein the first mask shadow and the first upper inorganic layer include a same material; and a second mask shadow spaced apart from the second protrusion with the pixel opening interposed between the second mask shadow and the second protrusion, wherein the second mask shadow and the second upper inorganic layer include a same material, and the first mask shadow and the second mask shadow respectively include different materials.

In an embodiment, the first mask shadow may include silicon oxide, and the second mask shadow includes silicon nitride.

In an embodiment, a height of the second protrusion in a direction perpendicular to the mask substrate may be equal to a height of the second mask shadow.

In an embodiment, a height of the first protrusion in the direction perpendicular to the mask substrate may be equal to a height of the first mask shadow.

In an embodiment, the mask substrate may include silicon, and the mask substrate have a circular shape in a plan view.

In an embodiment, the first mask shadow may include a first surface facing the second mask shadow and a second surface opposite the first surface, and the second mask shadow includes a third surface facing away from the first mask shadow and a fourth surface opposite the third surface.

In an embodiment, a width of the first surface in a direction parallel to the mask substrate may be greater than a width of the second surface, and a width of the third surface is greater than a width of the fourth surface.

In an embodiment, the mask shadow may have an inverse tapered shape.

In an embodiment, the first mask shadow may further include a first side surface connecting the first surface and the second surface, and the second mask shadow may further include a second side surface connecting the third surface and the fourth surface.

In an embodiment, a width of the first surface in a direction parallel to the mask substrate may be greater than a width of the second surface, and a width of the third surface is smaller than a width of the fourth surface.

In an embodiment of the disclosure, a first inclination angle formed between the second surface and the first side surface of the first mask shadow may be an obtuse angle; and a second inclination angle formed between the third surface and the second side surface of the second mask shadow may be an obtuse angle.

In an embodiment, the second side surface may protrude more toward the pixel opening than the first side surface.

In an embodiment, an undercut may be formed between the fourth surface and the first side surface.

In an embodiment of the disclosure, a deposition mask may further include a third upper inorganic layer positioned on the second upper inorganic layer and including a third protrusion that protrudes more toward the cell area than the side surface of the mask substrate, wherein the third upper inorganic layer and the first upper inorganic layer may include a same material.

In an embodiment, the mask shadow may further include a third mask shadow including the same material as the third upper inorganic layer and spaced apart from the third protrusion with the pixel opening interposed between the third mask shadow and the third protrusion.

In an embodiment, a side surface of the second mask shadow facing the pixel opening may protrude more toward the pixel opening than a side surface of the third mask shadow facing the pixel opening.

In an embodiment, the cell area may include a first cell area including a center of the cell area and a second cell area surrounding the first cell area, a first portion of the mask shadow overlapping the first cell area includes the first mask shadow and the second mask shadow, and a second portion of the mask shadow overlapping the second cell area may include the second mask shadow but may do not include the first mask shadow.

In an embodiment, in a plan view, the first cell area may be completely surrounded by the second cell area, and in the plan view, the second cell area may be completely surrounded by the cell peripheral area.

In an embodiment of the disclosure, a deposition mask may further include a grid area positioned between the cell area and the cell peripheral area, wherein the first protrusion and the second protrusion are sequentially stacked in a direction perpendicular to the mask substrate in a portion overlapping the grid area, and the mask substrate, the first upper inorganic layer, the second upper inorganic layer, and the mask membrane do not overlap the grid area.

In an embodiment, in a plan view, the cell area may be completely surrounded by the grid area, and in the plan view, the grid area is completely surrounded by the cell peripheral area.

In an embodiment, an electronic device includes a display device formed using a deposition mask; the deposition mask comprising: a mask substrate comprising a cell area and a cell peripheral area; a mask membrane positioned in the cell area of the mask substrate and comprising a pixel opening and a mask shadow surrounding the pixel opening; a first upper inorganic layer positioned on the cell peripheral area of the mask substrate and comprising a first protrusion that protrudes more toward the cell area than a side surface of the mask substrate; and a second upper inorganic layer positioned on the first upper inorganic layer and comprising a second protrusion that protrudes more toward the cell area than the side surface of the mask substrate, wherein the mask shadow comprises: a first mask shadow spaced apart from the first protrusion with the pixel opening interposed between the first mask shadow and the first protrusion, wherein the first mask shadow and the first upper inorganic layer comprise a same material; and a second mask shadow spaced apart from the second protrusion with the pixel opening interposed between the second mask shadow and the second protrusion, wherein the second mask shadow and the second upper inorganic layer comprise a same material, and the first mask shadow and the second mask shadow respectively comprise different materials.

According to the deposition mask according to an embodiment, by forming a mask membrane in a portion overlapping a cell region of a mask substrate, a deposition mask for manufacturing a high-resolution display panel may be provided.

The deposition mask according to an embodiment includes a mask shadow in which inorganic films having different physical properties are stacked, thereby providing a deposition mask with improved adhesion to the display panel.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a head mounted electronic device according to an embodiment;

FIG. 2 is an exploded perspective view illustrating an example of the head mounted electronic device of FIG. 1;

FIG. 3 is a perspective view illustrating a head mounted electronic device according to an embodiment;

FIG. 4 is an exploded perspective view illustrating a display device according to an embodiment;

FIG. 5 is a cross-sectional view illustrating an example in which a portion of a display panel according to an embodiment is cut;

FIG. 6 is a schematic plan view of a mask according to an embodiment;

FIG. 7 is an enlarged plan view of area A of FIG. 6;

FIG. 8 is a cross-sectional view taken along line X1-X1′ of FIG. 7;

FIG. 9 is an enlarged plan view of area B of FIG. 8;

FIG. 10 is an enlarged plan view of a mask shadow of FIG. 9;

FIG. 11 is a cross-sectional view taken along line X1-X1′ of FIG. 6, as still another embodiment;

FIG. 12 is an enlarged cross-sectional view of area E of FIG. 11;

FIG. 13 is a cross-sectional view taken along line X1-X1′ of FIG. 6, as still another embodiment;

FIG. 14 is an enlarged cross-sectional view of area G of FIG. 13;

FIG. 15 is a cross-sectional view taken along line X1-X1′ of FIG. 6, as still another embodiment;

FIG. 16 is an enlarged cross-sectional view of area I of FIG. 15;

FIG. 17 is an enlarged plan view of area A of FIG. 6, as still another embodiment; and

FIG. 18 is a cross-sectional view taken along line X9-X9′ of FIG. 17.

### DETAILED DESCRIPTION

The invention now will be described more fully hereinafter with reference to the accompanying drawings, in which various embodiments are illustrated. Aspects supported by the present disclosure may, however, be embodied in many different forms, and should not be construed as limited to the embodiments set forth herein. Rather, the example embodiments are provided such that this disclosure will be thorough and complete, and will fully convey the scope of example aspects of the present disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third,” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The terms “about” and “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

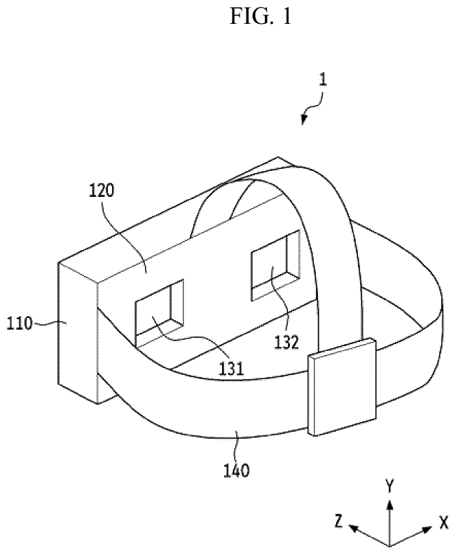

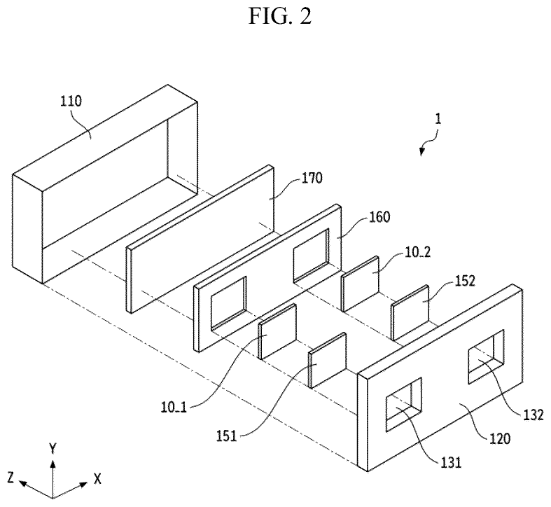

FIG. 1 is a perspective view illustrating a head mounted electronic device according to an embodiment. FIG. 2 is an exploded perspective view illustrating an example of the head mounted electronic device of FIG. 1.

Referring to FIGS. 1 and 2, a head mounted electronic device 1 according to an embodiment includes a display device accommodating portion 110, an accommodating portion cover 120, a first eyepiece 131, a second eyepiece 132, a head mounting band 140, a first display device 10_1, a second display device 10_2, a middle frame 160, a first optical member 151, a second optical member 152, a control circuit board 170, and a connector.

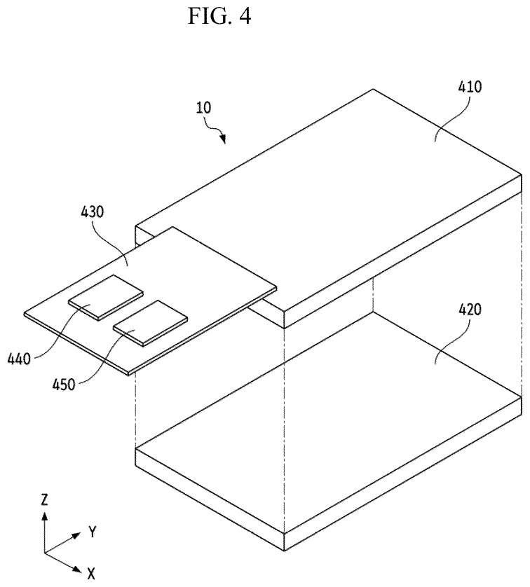

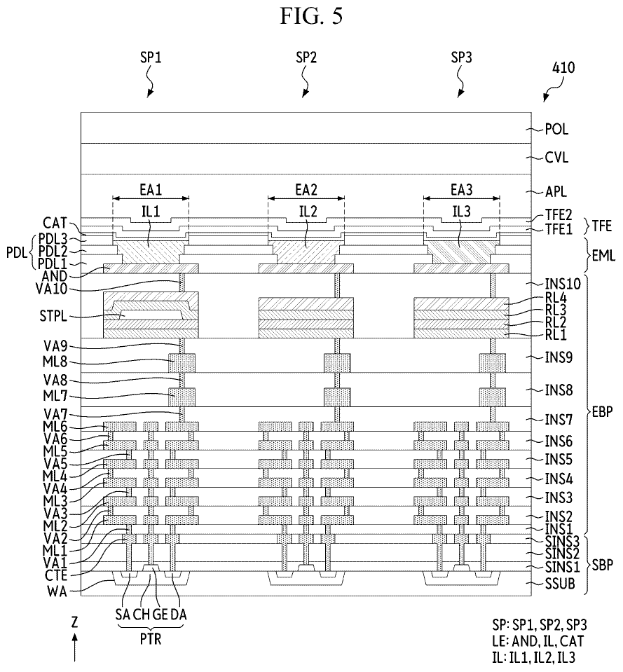

The first display device 10_1 provides an image to a user's left eye, and the second display device 10_2 provides an image to a user's right eye. Each of the first display device 10_1 and the second display device 10_2 is substantially the same as a display device 10 described with reference to FIGS. 4 and 5. Accordingly, descriptions of the first display device 10_1 and the second display device 10_2 will be replaced with descriptions with reference to FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 serves to support and fix the first display device 10_1, the second display device 10_2, and the control circuit board 170.

The control circuit board 170 may be disposed between the middle frame 160 and the display device accommodating portion 110. The control circuit board 170 may be connected to the first display device 10_1 and the second display device 10_2 through the connector. The control circuit board 170 may convert an image source input from the outside into digital video data DATA, and may transmit the digital video data DATA to the first display device 10_1 and the second display device 10_2 through the connector.

The control circuit board 170 may transmit digital video data DATA corresponding to a left eye image optimized for the user's left eye to the first display device 10_1, and may transmit digital video data DATA corresponding to a right eye image optimized for the user's right eye to the second display device 10_2. Alternatively, the control circuit board 170 may transmit the same digital video data DATA to the first display device 10_1 and the second display device 10_2.

The display device accommodating portion 110 serves to accommodate the first display device 10_1, the second display device 10_2, the middle frame 160, the first optical member 151, the second optical member 152, the control circuit board 170, and the connector. The accommodating portion cover 120 is disposed such that the accommodating portion cover 120 covers an opened surface of the display device accommodating portion 110. The accommodating portion cover 120 may include a first eyepiece 131 where the user's left eye is disposed and a second eyepiece 132 where the user's right eye is disposed. It is illustrated in FIGS. 1 and 2 that the first eyepiece 131 and the second eyepiece 132 are separately disposed, but the embodiment of the present specification is not limited thereto. The first eyepiece 131 and the second eyepiece 132 may be integrated into one.

The first eyepiece 131 may be aligned with the first display device 10_1 and the first optical member 151, and the second eyepiece 132 may be aligned with the second display device 10_2 and the second optical member 152. Therefore, the user may view an image of the first display device 10_1 magnified as a virtual image by the first optical member 151 through the first eyepiece 131, and may view an image of the second display device 10_2 magnified as a virtual image by the second optical member 152 through the second eyepiece 132.

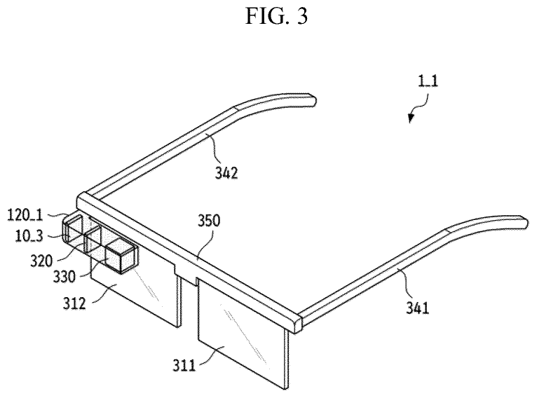

The head mounting band 140 serves to fix the display device accommodating portion 110 to a user's head such that the first eyepiece 131 and the second eyepiece 132 of the accommodating portion cover 120 are disposed on the user's left and right eyes, respectively. In an example in which the display device accommodating portion 110 is implemented in a lightweight and small size, the head mounted electronic device 1 may include eyeglass frames as illustrated in FIG. 3 instead of the head mounting band 140.

In some aspects, the head mounted electronic device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view illustrating a head mounted electronic device according to an embodiment.

Referring to FIG. 3, a head mounted electronic device 1_1 according to an embodiment may be a glasses-type display device in which a display device accommodating portion 120_1 is implemented in a lightweight and small size. The head mounted electronic device 1_1 according to an embodiment may include a display device 10_3, a left eye lens 311, a right eye lens 312, a support frame 350, eyeglass frame legs 341 and 342, an optical member 320, a light path conversion member 330, and a display device accommodating portion 120_1.

The display device 10_3 illustrated in FIG. 3 is substantially the same as the display device 10 described with reference to FIGS. 4 and 5. Accordingly, the descriptions of the first display device 10_1 and the second display device 10_2 will be replaced with the descriptions with reference to FIGS. 4 and 5.

The display device accommodating portion 120_1 may include the display device 10_3, the optical member 320, and the light path conversion member 330. As an image displayed on the display device 10_3 is magnified by the optical member 320 and a light path of the image is converted by the light path conversion member 330, the image may be provided to the user's right eye through the right eye lens 312. Accordingly, the user may view an augmented reality image in which a virtual image displayed on the display device 10_3 and a real image viewed through the right eye lens 312 are combined through the right eye.

It is illustrated in FIG. 3 that the display device accommodating portion 120_1 is disposed at a right distal end of the support frame 350, but the embodiment of the present specification is not limited thereto. For example, the display device accommodating portion 120_1 may be disposed at a left distal end of the support frame 350, and in this case, the image of the display device 10_3 may be provided to the user's left eye. Alternatively, the display device accommodating portion 120_1 may be disposed at both the left and right distal ends of the support frame 350. In this case, the user may view the image displayed on the display device 10_3 through both the user's left and right eyes.

FIG. 4 is an exploded perspective view illustrating a display device according to an embodiment.

Referring to FIG. 4, a display device 10 according to an embodiment is a device that displays a moving image or a still image. The display device 10 according to an embodiment may be applied to portable electronic devices such as, for example, a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 may be applied to a display unit of a television, a laptop computer, a monitor, a billboard, or the Internet of Things (IoT). Alternatively, the display device 10 may be applied to a smart watch, a watch phone, and a head mounted display (HMD) for implementing virtual reality and augmented reality.

The display device 10 according to an embodiment includes a display panel 410, a heat dissipation layer 420, a circuit board 430, a driving circuit 440, and a power supply circuit 450.

The display panel 410 may be formed in a planar shape similar to a quadrangle. For example, the display panel 410 may have a planar shape similar to a quadrangle having short sides in a first direction DR1 (X-axis direction) and long sides in a second direction DR2 (Y-axis direction) intersecting the first direction DR1 (X-axis direction). In the display panel 410, a corner where the short side in the first direction (X-axis direction) and the long side in the second direction (Y-axis direction) meet each other may be formed at a right angle or may be formed in a rounded shape such that the corner has a predetermined curvature. The planar shape of the display panel 410 is not limited to the quadrangle, and may be formed similarly to other polygons, circles, or ovals. A planar shape of the display device 10 may follow the planar shape of the display panel 410, but the embodiment of the present specification is not limited thereto.

The display panel 410 includes a display area that displays an image and a non-display area that does not display an image.

The display area includes a plurality of pixels, and each of the plurality of pixels includes a plurality of sub-pixels (SP1, SP2, and SP3 in FIG. 5). The plurality of sub-pixels SP1, SP2, and SP3 include a plurality of pixel transistors. The plurality of pixel transistors may be formed through a semiconductor process and may be disposed on a semiconductor substrate (SSUB in FIG. 5). For example, the plurality of pixel transistors may be formed of a complementary metal oxide semiconductor (CMOS).

The heat dissipation layer 420 may overlap the display panel 410 in a third direction (Z-axis direction), which is a thickness direction of the display panel 410. The heat dissipation layer 420 may be disposed on one surface of the display panel 410, for example, a rear surface of the display panel 410. The heat dissipation layer 420 serves to dissipate heat generated from the display panel 410. The heat dissipation layer 420 may include a metal layer such as, for example, graphite, silver (Ag), copper (Cu), or aluminum (Al) having high thermal conductivity.

The circuit board 430 may be electrically connected to a plurality of pads PD of a pad area PDA of the display panel 410 by using a conductive adhesive member such as, for example, an anisotropic conductive film. The circuit board 430 may be a flexible printed circuit board or flexible film formed of a flexible material. It is illustrated in FIG. 4 that the circuit board 430 is unfolded, but the circuit board 430 may be bent. In this case, one end of the circuit board 430 may be disposed on the rear surface of the display panel 410. One end of the circuit board 430 may be an opposite end of the other end of the circuit board 430 connected to the plurality of pads PD of the pad area PDA of the display panel 410 by using a conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate a plurality of panel driving voltages according to a power voltage from the outside.

The driving circuit 440 and the power supply circuit 450 may be each formed as an integrated circuit (IC) and attached to one surface of the circuit board 430.

FIG. 5 is a cross-sectional view illustrating an example in which a portion of a display panel according to an embodiment is cut. For example, FIG. 5 illustrates a partial cross-sectional structure of a display area including a plurality of sub-pixels (SP1, SP2, and SP3 in FIG. 5).

Referring to FIG. 5, the display panel 410 includes a semiconductor backplane SBP, a light emitting element backplane EBP, a light emitting element layer EML, an encapsulation layer TFE, an optical layer OPL, and a cover layer CVL.

The semiconductor backplane SBP includes a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively.

The semiconductor substrate SSUB may be a silicon substrate, a germanium substrate, or a silicon-germanium substrate. The semiconductor substrate SSUB may be a substrate doped with a first-type impurity (or first-type impurities). A plurality of well areas WA may be disposed on an upper surface of the semiconductor substrate SSUB. The plurality of well areas WA may be areas doped with second-type impurities. The second-type impurity may be different from the first-type impurity described herein. In an example in which the first-type impurity is a p-type impurity, the second-type impurity may be an n-type impurity. Alternatively, when the first-type impurity is an n-type impurity, the second-type impurity may be a p-type impurity.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that is not bent, and the polymer resin substrate may be a flexible substrate that may be bent or curved.

Each of the plurality of well areas WA includes a source area SA corresponding to a source electrode of the pixel transistor PTR, a drain area DA corresponding to a drain electrode of the pixel transistor PTR, and a channel area CH disposed between the source area SA and the drain area DA.

Each of the source area SA and the drain area DA may be an area doped with first-type impurities. A gate electrode GE of the pixel transistor PTR may overlap the well area WA in the third direction (Z-axis direction). The channel area CH may overlap the gate electrode GE in the third direction (Z-axis direction). The source area SA may be disposed on one side of the gate electrode GE, and the drain area DA may be disposed on the other side of the gate electrode GE.

A first semiconductor insulating film SINS1 may be disposed on the semiconductor substrate SSUB. The first semiconductor insulating film SINS1 may be formed as a silicon nitride (SiCN) or silicon oxide (SiOx)-based inorganic film, but the embodiment of the present specification is not limited thereto.

A semiconductor insulating film SINS2 may be disposed on the first semiconductor insulating film SINS1. The second semiconductor insulating film SINS2 may be formed as a silicon oxide (SiOx)-based inorganic film, but the embodiment of the present specification is not limited thereto.

A plurality of contact terminals CTE may be disposed on the second semiconductor insulating film SINS2. Each of the plurality of contact terminals CTE may be connected to any one of the gate electrode GE, the source area SA, and the drain area DA of each of the plurality of pixel transistors PTR through a hole penetrating through the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating film SINS3 may be disposed on a side surface of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOx)-based inorganic film, but the embodiment of the present specification is not limited thereto.

The light emitting element backplane EBP includes first to eighth metal layers ML1 to ML8, reflective metal layers RL1 to RL4, a plurality of vias VA1 to VA10, and a step layer STPL. In some aspects, the light emitting element backplane EBP includes a plurality of interlayer insulating films INS1 to INS10 disposed between the first to sixth metal layers ML1 to ML6.

The first to eighth metal layers ML1 to ML8 serve to implement a circuit of a sub-pixel SP by connecting the plurality of contact terminals CTE exposed from the semiconductor backplane SBP.

A first interlayer insulating film INS1 may be disposed on the semiconductor backplane SBP. Each of the first vias VA1 may penetrate through the first interlayer insulating film INSI and be connected to the contact terminal CTE exposed from the semiconductor backplane SBP. Each of the first metal layers ML1 may be disposed on the first interlayer insulating film INS1 and may be connected to the first via VA1.

A second interlayer insulating film INS2 may be disposed on the first interlayer insulating film INS1 and the first metal layers ML1. Each of the second vias VA2 may be connected to the first metal layer ML1 exposed by penetrating through the second interlayer insulating film INS2. Each of the second metal layers ML2 may be disposed on the second interlayer insulating film INS2 and may be connected to the second via VA2.

A third interlayer insulating film INS3 may be disposed on the second interlayer insulating film INS2 and the second metal layers ML2. Each of the third vias VA3 may be connected to the second metal layer ML2 exposed by penetrating through the third interlayer insulating film INS3. Each of the third metal layers ML3 may be disposed on the third interlayer insulating film INS3 and may be connected to the third via VA3.

A fourth interlayer insulating film INS4 may be disposed on the third interlayer insulating film INS3 and the third metal layers ML3. Each of the fourth vias VA4 may be connected to the third metal layer ML3 exposed by penetrating through the fourth interlayer insulating film INS4. Each of the fourth metal layers ML4 may be disposed on the fourth interlayer insulating film INS4 and may be connected to the fourth via VA4.

A fifth interlayer insulating film INS5 may be disposed on the fourth interlayer insulating film INS4 and the fourth metal layers ML4. Each of the fifth vias VA5 may be connected to the fourth metal layer ML4 exposed by penetrating through the fifth interlayer insulating film INS5. Each of the fifth metal layers ML5 may be disposed on the fifth interlayer insulating film INS5 and may be connected to the fifth via VA5.

A sixth interlayer insulating film INS6 may be disposed on the fifth interlayer insulating film INS5 and the fifth metal layers ML5. Each of the sixth vias VA6 may be connected to the fifth metal layer ML5 exposed by penetrating through the sixth interlayer insulating film INS6. Each of the sixth metal layers ML6 may be disposed on the sixth interlayer insulating film INS6 and may be connected to the sixth via VA6.

A seventh interlayer insulating film INS7 may be disposed on the sixth interlayer insulating film INS6 and the sixth metal layers ML6. Each of the seventh vias VA7 may be connected to the sixth metal layer ML6 exposed by penetrating through the seventh interlayer insulating film INS7. Each of the seventh metal layers ML7 may be disposed on the seventh interlayer insulating film INS7 and may be connected to the seventh via VA7.

An eighth interlayer insulating film INS8 may be disposed on the seventh interlayer insulating film INS7 and the seventh metal layers ML7. Each of the eighth vias VA8 may be connected to the seventh metal layer ML7 exposed by penetrating through the eighth interlayer insulating film INS8. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may be formed of substantially the same material. The first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth vias VA1 to VA8 may be formed of substantially the same material. The first to eighth interlayer insulating films INSI to INS8 may be formed as a silicon oxide (SiOx)-based inorganic film, but the embodiment of the present specification is not limited thereto.

A thickness of the first metal layer ML1, a thickness of the second metal layer ML2, a thickness of the third metal layer ML3, a thickness of the fourth metal layer ML4, a thickness of the fifth metal layer ML5, and a thickness of the sixth metal layer ML6 may be greater than a thickness of the first via VA1, a thickness of the second via VA2, a thickness of the third via VA3, a thickness of the fourth via VA4, a thickness of the fifth via VA5, and a thickness of the sixth via VA6, respectively. Each of the thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5, and the thickness of the sixth metal layer ML6 may be substantially the same.

Each of a thickness of the seventh metal layer ML7 and a thickness of the eighth metal layer ML8 may be greater than each of the thickness of the first metal layer ML1, the thickness of the second metal layer ML2, the thickness of the third metal layer ML3, the thickness of the fourth metal layer ML4, the thickness of the fifth metal layer ML5, and the thickness of the sixth metal layer ML6. Each of the thickness of the seventh metal layer ML7 and the thickness of the eighth metal layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh metal layer ML7 and the thickness of the eighth metal layer ML8 may be substantially the same.

A ninth interlayer insulating film INS9 may be disposed on the eighth interlayer insulating film INS8 and the eighth metal layers ML8. The ninth interlayer insulating film INS9 may be formed as a silicon oxide (SiOx)-based inorganic film, but the embodiment of the present specification is not limited thereto.

Each of the ninth vias VA9 may be connected to the eighth metal layer ML8 exposed by penetrating through the ninth interlayer insulating film INS9. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of first reflective electrodes RL1 may be disposed on the ninth interlayer insulating film INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof.

Each of second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the second reflective electrodes RL2 may be formed of titanium nitride (TiN).

In a portion overlapping the first sub-pixel SP1, a step layer STPL may be disposed on the second reflective electrode RL2. The step layer STPL may not be disposed in a portion overlapping the second sub-pixel SP2 and the third sub-pixel SP3. The step layer STPL may be formed of a silicon carbon nitride (SiCN) or silicon oxide (SiOx)-based inorganic film, but the embodiments of the present specification are not limited thereto.

In a portion overlapping the first sub-pixel SP1, a third reflective electrode RL3 may be disposed on the second reflective electrode RL2 and the step layer STPL. In a portion overlapping the second and third sub-pixels SP2 and SP3, the third reflective electrode RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. At least one of the first reflective electrode RL1, the second reflective electrode RL2, and the third reflective electrode RL3 may be omitted.

Each of fourth reflective electrodes RL4 may be disposed on the third reflective electrode RL3. The fourth reflective electrode RL4 may include a metal having a high reflectance to be advantageous in reflecting light. The fourth reflective electrode RL4 may be formed of aluminum (Al), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of an APC alloy and ITO, but the embodiment of the present specification is not limited thereto.

A tenth interlayer insulating film INS10 may be disposed on the ninth interlayer insulating film INS9 and the fourth reflective electrode RL4. The tenth interlayer insulating film INS10 may be formed as a silicon oxide (SiOx)-based inorganic film, but the embodiment of the present specification is not limited thereto.

Each of the tenth vias VA10 may be connected to the ninth metal layer ML9 exposed by penetrating through the tenth interlayer insulating film INS10. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. Due to the step layer STPL, a thickness of the tenth via VA10 in the first sub-pixel SP1 may be smaller than a thickness of the tenth via VA10 in each of the second and third sub-pixels SP2 and SP3.

The light emitting element layer EML may be disposed on the light emitting element backplane EBP. The light emitting element layer EML may include light emitting elements LE each including a first electrode AND, a light emitting layer IL, and a second electrode CAT, and a pixel defining layer PDL.

The first electrode AND may be disposed on the tenth interlayer insulating film INS10 and may be connected to the tenth via VA10. The first electrode AND may be connected to the drain area DA or the source area SA of the pixel transistor PTR through the tenth via VA10, the first to fourth reflective electrodes RL1 to RL4, the first to ninth vias VA1 to VA9, the first to eighth metal layers ML1 to ML8, and the contact terminal CTE. The first electrode AND may be formed of any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the first electrode AND may be formed of titanium nitride (TiN).

The pixel defining layer PDL may be disposed on a partial area of the first electrode AND. The pixel defining layer PDL may cover an edge of the first electrode AND. The pixel defining layer PDL serves to partition the first light emitting areas EA1, the second light emitting areas EA2, and the third light emitting areas EA3.

The first light emitting area EA1 may be defined as an area in which the first electrode AND, the first light emitting layer IL1, and the second electrode CAT are sequentially stacked in the first sub-pixel SP1 to emit light. The second light emitting area EA2 may be defined as an area in which the first electrode AND, the second light emitting layer IL2, and the second electrode CAT are sequentially stacked in the second sub-pixel SP2 to emit light. The third light emitting area EA3 may be defined as an area in which the first electrode AND, the third light emitting layer IL3, and the second electrode CAT are sequentially stacked in the third sub-pixel SP3 to emit light.

The pixel defining layer PDL may include first to third pixel defining layers PDL1, PDL2, and PDL3. The first pixel defining layer PDL1 may be disposed on the edge of the first electrode AND, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed as a silicon oxide (SiOx)-based inorganic film, but the embodiment of the present specification is not limited thereto.

The light emitting layer IL may include a first light emitting layer IL1, a second light emitting layer IL2, and a third light emitting layer IL3. The first light emitting layer IL1, the second light emitting layer IL2, and the third light emitting layer IL3 may emit light of different colors. As an example, the first light emitting layer IL1 may emit red light, the second light emitting layer IL2 may emit green light, and the third light emitting layer IL3 may emit blue light, but embodiments of the present disclosure are not limited thereto.

The first to third light emitting layers IL1, IL2, and IL3 disposed adjacent to each other in the first direction (X-axis direction) may be disconnected by the pixel defining layer PDL. The display panel 410 according to an embodiment may prevent leakage current between the sub-pixels SP1, SP2, and SP3 disposed adjacent to each other and prevent a color interference phenomenon by disconnecting the first to third light emitting layers IL1, IL2, and IL3 disposed adjacent to each other.

The second electrode CAT may be disposed on the light emitting layer IL. The second electrode CAT may be a common electrode. The second electrode CAT may be formed of a transparent conductive material (TCO) such as, for example, ITO or IZO capable of transmitting light, or a semi-transmissive conductive material such as, for example, magnesium (Mg), silver (Ag), or an alloy of magnesium (Mg) and silver (Ag). In an example in which the second electrode CAT is formed of a semi-transmissive conductive material, light emission efficiency may be increased in each of the first to third sub-pixels SP1, SP2, and SP3 by micro cavities.

The encapsulation layer TFE may be disposed on the light emitting element layer EML. The encapsulation layer TFE may include at least one inorganic film to prevent oxygen or moisture from permeating into the light emitting element layer EML. For example, the encapsulation layer TFE may include a first encapsulation layer TFE1 and a second encapsulation layer TFE2.

The first encapsulation layer TFE1 may be disposed on the second electrode CAT, and the second encapsulation layer TFE2 may be disposed on the first encapsulation layer TFE1. The first encapsulation layer TFE1 and the second encapsulation layer TFE2 may be formed as a multi-film in which one or more inorganic films of a silicon nitride layer (SiNx), a silicon oxynitride layer (SiON), a silicon oxide layer (SiOx), a titanium oxide layer (TiOx), and an aluminum oxide layer (AlOx) are alternately stacked.

An adhesive layer APL may be a layer for increasing an interfacial adhesion between the encapsulation layer TFE and the cover layer CVL. The adhesive layer APL may be an organic film formed of an acryl resin, an epoxy resin, a phenolic resin, a polyamide resin, a polyimide resin, or the like.

The cover layer CVL may be disposed on the adhesive layer APL. The cover layer CVL may be a glass substrate or a polymer resin such as, for example, resin. In an example in which the cover layer CVL is a glass substrate, the cover layer CVL may serve as an encapsulation substrate, and in an example in which the cover layer CVL is a polymer resin such as, for example, resin, the cover layer CVL may be applied directly on the adhesive layer APL.

A polarizing plate POL may be disposed on one surface of the cover layer CVL. The polarizing plate POL may be a structure for preventing deterioration in visibility due to reflection of external light. The polarizing plate POL may include a linear polarizing plate and a phase retardation film. As an example, the phase retardation film may be a N4 (quarter-wave) plate, but the embodiment of the present specification is not limited thereto.

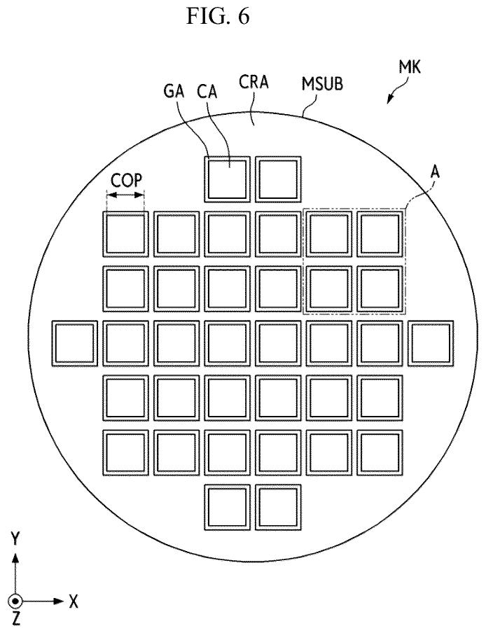

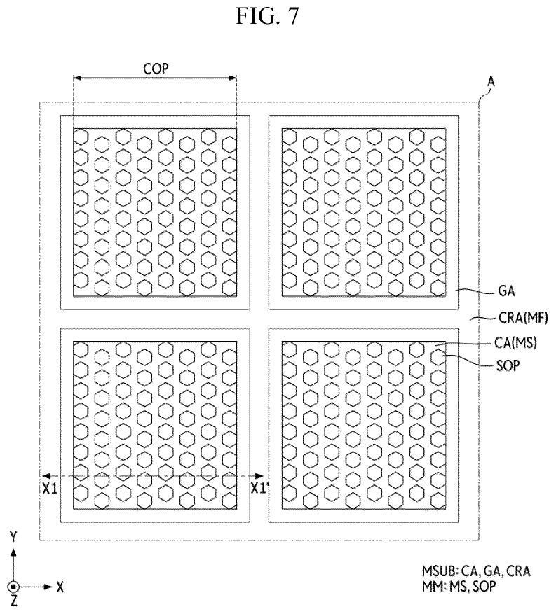

FIG. 6 is a schematic plan view of a mask according to an embodiment. FIG. 7 is an enlarged plan view of area A of FIG. 6. The mask according to an embodiment illustrated in FIG. 6 may be used in a process of depositing at least a portion of the light emitting layer IL of the display panel 410 described with reference to FIG. 5.

Referring to FIGS. 6 and 7, a mask MK according to an embodiment may be a mask used to manufacture an ultra-high resolution display. As an example, the mask MK may be a mask used to manufacture a display included in an extended reality device (XR device) such as, for example, a VR device, AR device, or MR device.

The mask MK according to an embodiment may be used to perform a deposition process of the sub-pixels (SP1, SP2, and SP3 in FIG. 5) on a silicon wafer rather than a large-area substrate used in the conventional display. In the case of the display included in the extended reality device, since a screen of the display is positioned directly in front of the user's eyes, the display may have a small screen rather than a large-area screen. In some aspects, since the display is positioned close to the user's eyes, ultra-high resolution may be required. For example, the display included in the extended reality device may require resolution of approximately 1000 PPI or more, and preferably may require ultra-high resolution of 2000 PPI or more. Therefore, the mask MK according to an embodiment may be a mask used to manufacture such an ultra-high resolution display. The mask MK according to an embodiment may include all of masks MK1, MK3, MK5, MK7, and MK9 described later.

The mask MK according to an embodiment may include a mask substrate MSUB.

The mask substrate MSUB according to an embodiment may include a silicon wafer. Since the silicon wafer may be processed more finely and precisely than the large-area substrate by utilizing technologies developed in the semiconductor process, the silicon wafer may be employed as a substrate of the ultra-high resolution display. The mask MK according to an embodiment may use the same silicon wafer to form pixels on the silicon wafer of such an ultra-high resolution display.

The mask substrate MSUB according to an embodiment may have a shape corresponding to the silicon wafer of the ultra-high resolution display. For example, the mask substrate MSUB may have the same size or shape as the silicon wafer of the ultra-high resolution display. However, the mask substrate MSUB is not limited thereto, and may also include a large-area substrate. For example, the mask substrate MSUB may also include materials such as, for example, glass, quartz, and polymer resin.

The mask substrate MSUB according to an embodiment may include a plurality of cell areas CA, a plurality of grid areas GA, and a cell peripheral area CRA.

According to an embodiment, a plurality of cell areas CA may be formed, and may be positioned to be spaced apart from each other. The cell area CA may be a portion positioned to overlap the mask opening COP.

In a plan view, the cell area CA may be an area where a mask membrane MM overlaps. The mask membrane MM may include a pixel opening SOP and a mask shadow MS. In a plan view, the mask shadow MS may be integrally formed to entirely surround the pixel opening SOP. In other words, In a plan view, the mask shadow MS may be a pattern formed integrally while exposing the pixel opening SOP.

The grid area GA according to an embodiment may be positioned between the cell area CA and the cell peripheral area CRA. In a plan view, the grid area GA may be positioned to completely surround the cell area CA. In other words, In a plan view, the grid area GA may completely surround the mask opening COP.

The cell peripheral area CRA according to an embodiment may be positioned to surround the grid area GA. The cell peripheral area CRA may be positioned to surround each cell area CA and grid area GA.

In a plan view, the cell peripheral area CRA may be an area where the mask frame MF overlaps. The mask frame MF may be an area that supports the mask MK. In a plan view, the mask frame MF may entirely surround the mask membrane MM. In other words, In a plan view, the mask frame MF may entirely surround the mask opening COP.

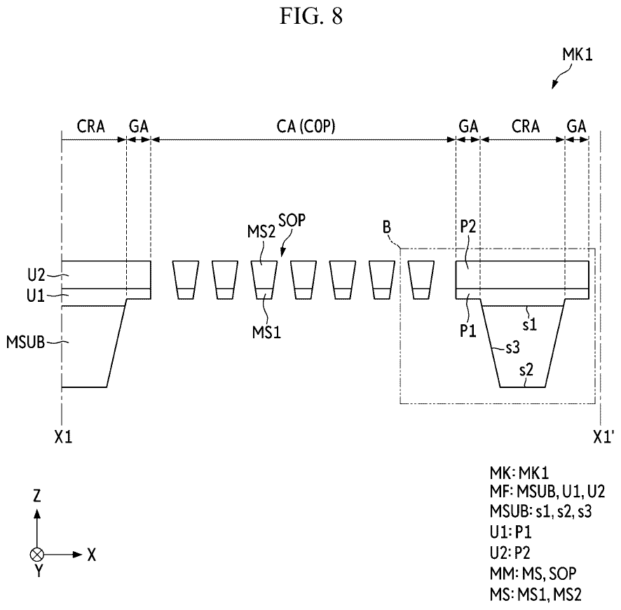

FIG. 8 is a cross-sectional view taken along line X1-X1′ of FIG. 7.

Referring to FIG. 8, the mask frame MF according to an embodiment may be positioned in a portion overlapping the cell peripheral area CRA in cross-section. The mask frame MF may include a mask substrate MSUB, a first upper inorganic layer U1, and a second upper inorganic layer U2.

In some embodiments, the mask substrate MSUB may include an upper surface s1, a lower surface s2, and a side surface s3. The upper surface s1 may be a surface facing the first upper inorganic layer U1, the lower surface s2 may be a surface opposite to the upper surface s1, and the side surface s3 may be a surface connecting the upper surface s1 and the lower surface s2. The side surface s3 of the mask substrate MSUB may be an inclined surface. This may be caused by a portion of the mask substrate MSUB being removed through an etching process during the manufacturing process of the mask MK.

The first upper inorganic layer U1 according to an embodiment may be positioned on the mask substrate MSUB. The first upper inorganic layer U1 may be in contact with the upper surface s1 of the mask substrate MSUB and may entirely cover the upper surface s1.

The first upper inorganic layer U1 according to an embodiment may include a first protrusion P1 that protrudes more toward the cell area CA than the side surface s3 of the mask substrate MSUB. The first protrusion P1 of the first upper inorganic layer U1 may be positioned in a portion overlapping the grid area GA.

The first upper inorganic layer U1 may include an inorganic insulating material. As an example, the first upper inorganic layer U1 may include any one of silicon oxide, silicon nitride, and silicon oxynitride.

The second upper inorganic layer U2 according to an embodiment may be positioned on the first upper inorganic layer U1. The second upper inorganic layer U2 may be in contact with the first upper inorganic layer U1 and may entirely cover the first upper inorganic layer U1.

The second upper inorganic layer U2 according to an embodiment may include a second protrusion P2 that protrudes more toward the cell area CA than the side surface s3 of the mask substrate MSUB. The second protrusion P2 of the second upper inorganic layer U2 may be positioned in a portion overlapping the grid area GA.

The second upper inorganic layer U2 may include an inorganic insulating material.

As an example, the second upper inorganic layer U2 may include any one of silicon oxide, silicon nitride, and silicon oxynitride. The second upper inorganic layer U2 and the mask shadow MS may include the same material, example aspects of which will be described later. Details will be described later.

The first upper inorganic layer U1 and the second upper inorganic layer U2 according to an embodiment may have different materials. As an example, when the first upper inorganic layer U1 includes silicon oxide, the second upper inorganic layer U2 may include any one of silicon nitride and silicon oxynitride, excluding silicon oxide.

The first upper inorganic layer U1 and the second upper inorganic layer U2 according to an embodiment may have different stress physical properties. As an example, when the first upper inorganic layer U1 includes an inorganic insulating material having compressive stress, the second upper inorganic layer U2 may include an inorganic insulating material having tensile stress.

The mask MK according to an embodiment may reduce stress applied to the mask MK1 by forming the first upper inorganic layer U1 and the second upper inorganic layer U2 to have stresses of different physical properties.

The grid area GA may be a portion where the first protrusion P1 and the second protrusion P2 are positioned. In a portion overlapping the grid area GA, the second protrusion P2 of the second upper inorganic layer U2 may be positioned in contact with the first protrusion P1 of the first upper inorganic layer U1. The first protrusion P1 of the first upper inorganic layer U1 and the second protrusion P2 of the second upper inorganic layer U2 may not overlap the mask substrate MSUB and the mask membrane MM in the third direction (Z-axis direction). In other words, the mask substrate MSUB and the mask membrane MM may not overlap the grid area GA.

The mask membrane MM according to an embodiment may be positioned in a portion overlapping the cell area CA. The mask membrane MM may include a plurality of mask shadows MS and pixel openings SOP.

The pixel opening SOP may be positioned between the plurality of mask shadows MS adjacent to each other. The pixel opening SOP may be named “hole” or “mask hole.” The plurality of pixel openings SOP may penetrate through the mask frame MF along a thickness direction (e.g., third direction (Z-axis direction)) of the mask MK. The plurality of pixel openings SOP may be formed by etching portions of the mask substrate MSUB, the first upper inorganic layer U1, and the second upper inorganic layer U2 from a direction of the lower surface s2 of the mask substrate MSUB during the manufacturing process of the mask MK.

The mask shadow MS according to an may be positioned to surround the pixel openings SOP. In an example in which a deposition material is evaporated from a deposition source inside a deposition device, the plurality of mask shadows MS may serve as a blocking portion that masks a substrate to be deposited (e.g., the display panel 410 or the backplane substrate). Accordingly, the deposition material generated from the deposition source may be deposited on a surface of the substrate to be deposited (e.g., the display panel 410 or the backplane substrate) through the pixel openings SOP.

The mask shadow MS may be spaced apart from the mask frame MF with the pixel opening SOP (or multiple pixel openings SOP) interposed between the mask shadow MS and the mask frame MF.

In some embodiments, the mask shadow MS included in the mask MK1 may include a first mask shadow MS1 and a second mask shadow MS2. The first mask shadow MS1 and the second mask shadow MS2 may be sequentially stacked in the third direction (Z-axis direction).

The first mask shadow MS1 may be spaced apart from the first protrusion P1 of the first upper inorganic layer U1 with the pixel opening SOP interposed between the first mask shadow MS1 and the first protrusion P1. The first mask shadow MS1 and the first upper inorganic layer U1 may include the same material. In a process of manufacturing the mask MK1, the first upper inorganic layer U1 and the first mask shadow MS1 may be integrally formed, and then formed into the shapes illustrated in FIG. 8 through a subsequent etching process.

The second mask shadow MS2 may be spaced apart from the second protrusion P2 of the second upper inorganic layer U2 with the pixel opening SOP interposed between the second mask shadow MS2 and the second protrusion P2. The second mask shadow MS2 and the second upper inorganic layer U2 may include the same material. In a process of manufacturing the mask MK1, the second upper inorganic layer U2 and the second mask shadow MS2 may be integrally formed, and then formed into the illustrated shapes through a subsequent etching process.

Accordingly, the first mask shadow MS1 and the second mask shadow MS2 may respectively include different materials, and thus may include different stress physical properties. As an example, the first mask shadow MS1 may include an inorganic insulating material having compressive stress, and the second mask shadow MS2 may include an inorganic insulating material having tensile stress. However, embodiments of the present disclosure are not limited thereto. Other redundant descriptions will be omitted.

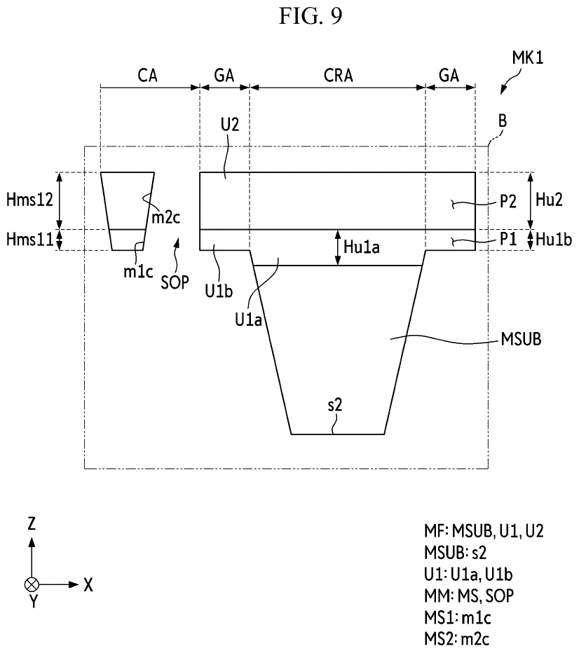

FIG. 9 is an enlarged plan view of area B of FIG. 8.

Referring to FIG. 9, the first upper inorganic layer U1 according to an embodiment may include a first portion U1a and a second portion U1b having different heights. The first portion U1a may be a portion overlapping the cell peripheral area CRA, and the second portion U1b may be a portion overlapping the grid area GA. The first portion U1a may be positioned at a central portion of the first upper inorganic layer U1 and may occupy most of the area of the first upper inorganic layer U1. In some aspects, the second portion U1b may be positioned at the edge of the first upper inorganic layer U1 and may be a portion facing the cell area CA. The second portion U1b may be a portion including the first protrusion P1 of the first upper inorganic layer U1.

In a process of manufacturing the mask MK1, the first upper inorganic layer U1 may be partially etched by an etching process performed in the direction of the lower surface s2 of the mask substrate MSUB. As a result, the first upper inorganic layer U1 may have the first portion U1a and the second portion U1b having different heights.

A height HU1a of the first portion U1a of the first upper inorganic layer U1 may be higher than a height Hu1b of the second portion U1b of the first upper inorganic layer U1.

The second upper inorganic layer U2 according to an embodiment may entirely cover the first portion U1a and the second portion U1b of the first upper inorganic layer U1. The second upper inorganic layer U2 may have the same height Hu2 in a portion overlapping the cell peripheral area CRA and the grid area GA.

The mask shadow MS according to an embodiment may be spaced apart from the second portion U1b of the first upper inorganic layer U1 with the pixel opening SOP interposed between the mask shadow MS and the second portion U1b. A height Hms11 of the first mask shadow MS1 may be equal to the height Hu1b of the second portion U1b of the first upper inorganic layer U1, but is not limited thereto. In some aspects, a height Hms12 of the second mask shadow MS2 may be equal to the height Hu2 of the second upper inorganic layer U2, but is not limited thereto.

In some embodiments, the first mask shadow MS1 may include a first side surface m1c. The first side surface m1c of the first mask shadow MS1 may be a surface facing the pixel opening SOP. The first side surface m1c of the first mask shadow MS1 may face the first protrusion P1 with the pixel opening SOP interposed between the first side surface m1c and the first protrusion P1.

In some embodiments, the second mask shadow MS2 may include a second side surface m2c. The second side surface m2c of the second mask shadow MS2 may be a surface facing the pixel opening SOP. The second side surface m2c of the second mask shadow MS2 may face the second protrusion P2 with the pixel opening SOP interposed between the second side surface m2c and the second protrusion P2.

The height Hms11 of the first mask shadow MS1 included in the mask MK1 may be lower than the height Hms12 of the second mask shadow MS2, but is not limited thereto.

In some embodiments, the mask shadow MS included in the mask MK1 may have an inverse tapered shape. Details will be described later.

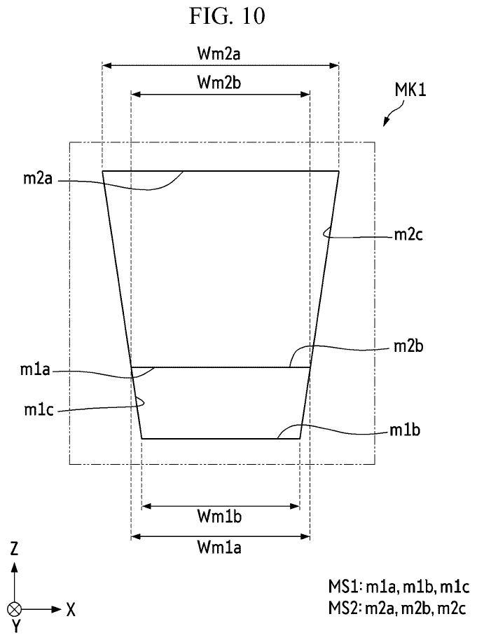

FIG. 10 is an enlarged plan view of a mask shadow of FIG. 9.

Referring to FIG. 10, the first mask shadow MS1 according to an embodiment may include a first surface m1a and a second surface m1b in addition to the first side surface m1c. The first surface m1a of the first mask shadow MS1 may be a surface facing the second mask shadow MS2, the second surface m1b of the first mask shadow MS1 may be a surface opposing the first surface m1a, and the first side surface m1c of the first mask shadow MS1 may be a surface connecting the first surface m1a and the second surface m1b. The first side surface m1c of the first mask shadow MS1 may be an inclined surface.

In some embodiments, a width Wm1b of the second surface m1b of the first mask shadow MS1 in the first direction (X-axis direction) may be smaller than a width Wm1a of the first surface m1a of the first mask shadow MS1.

In a process of manufacturing the mask MK1, a portion of the first mask shadow MS1 may be removed by an etching process performed in a direction of the lower surface s2 of the mask substrate MSUB. Therefore, the first side surface m1c of the first mask shadow MS1 may be formed as an inclined surface, and the width Wm1b of the second surface m1b may be smaller than the width Wm1a of the first surface m1a. In other words, it may be seen that a portion of the first mask shadow MS1 is etched by an etching process performed in a rear direction of the mask substrate MSUB in the process of manufacturing the mask MK1 through the shapes of the first surface m1a, the second surface m1b, and the first side surface m1c of the first mask shadow MS1 included in the mask MK1.

The second mask shadow MS2 according to an embodiment may include a third surface m2a and a fourth surface m2b in addition to the second side surface m2c. The fourth surface m2b of the second mask shadow MS2 may be a surface facing the first mask shadow MS1, the third surface m2a of the second mask shadow MS2 may be a surface opposing the fourth surface m2b, and the second side surface m2c of the second mask shadow MS2 may be a surface connecting the third surface m2a and the fourth surface m2b. The second side surface m2c of the second mask shadow MS2 may be an inclined surface. The first side surface m1c of the first mask shadow MS1 and the second side surface m2c of the second mask shadow MS2 may be positioned on the same line, but are not limited thereto. For example, in some cases, the first side surface m1c may protrude further outward in the X-axis direction compared to the second side surface m2c. Alternatively, for example, the second side surface m2c may protrude further outward in the X-axis direction compared to the first side surface m1c.

In some embodiments, a width Wm2b of the fourth surface m2b of the second mask shadow MS2 in the first direction (X-axis direction) may be smaller than a width Wm2a of the third surface m2a of the second mask shadow MS2.

In a process of manufacturing the mask MK1, a portion of the second mask shadow MS2 may be removed by an etching process performed in a direction of the lower surface s2 of the mask substrate MSUB. Therefore, the second side surface m2c of the second mask shadow MS2 may be formed as an inclined surface, and the width Wm2b of the fourth surface m2b may be smaller than the width Wm2a of the third surface m2a. In other words, it may be seen that a portion of the second mask shadow MS2 is etched by an etching process performed in a rear direction of the mask substrate MSUB in the process of manufacturing the mask MK1 through the shapes of the third surface m2a, the fourth surface m2b, and the second side surface m2c of the second mask shadow MS2 included in the mask MK1.

Referring to FIGS. 8 to 10, the mask MK1 according to an embodiment may support adjustments to the degree of bending of the mask shadow MS by forming the first mask shadow MS1 and the second mask shadow MS2 to have stresses of different physical properties. As a result, the mask MK1 according to an embodiment may have improved adhesion between the display panel (410 in FIG. 5) and the mask MK1 during the deposition process.

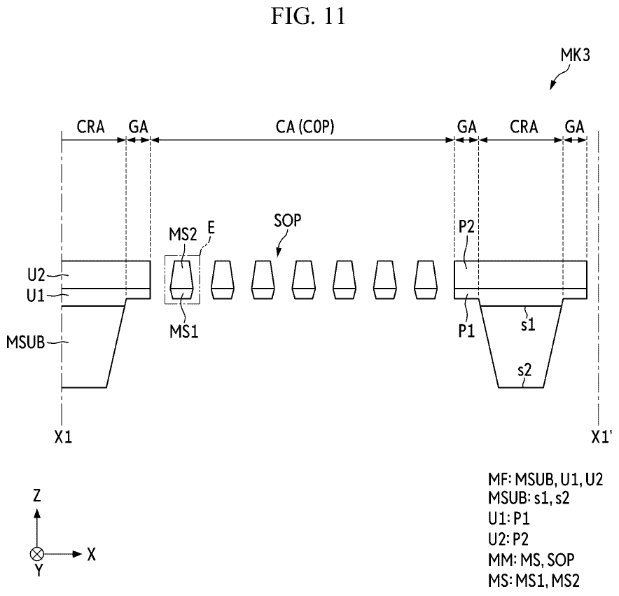

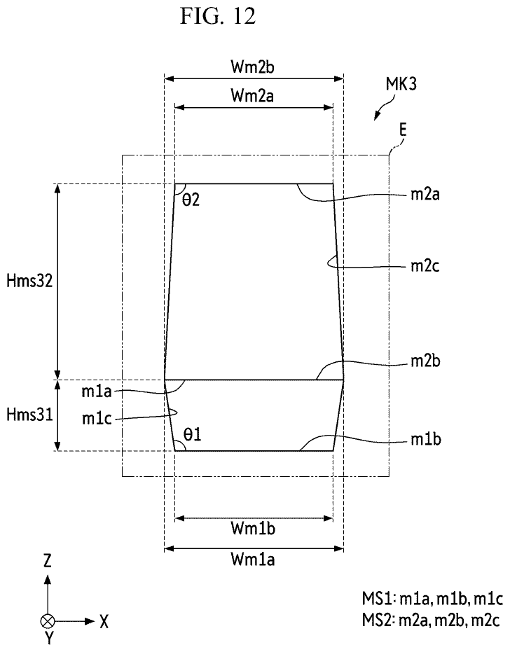

FIG. 11 is a cross-sectional view taken along line X1-X1′ of FIG. 6, as still another embodiment. FIG. 12 is an enlarged cross-sectional view of area E of FIG. 11.

Referring to FIGS. 11 and 12, a mask shadow MS included in a mask MK3 may have a different shape from the mask shadow MS included in the mask MK1.

The mask shadow MS included in the mask MK3 may include a first mask shadow MS1 and a second mask shadow MS2 that are stacked in the third direction (Z-axis direction). The first mask shadow MS1 may be spaced apart from the first protrusion P1 of the first upper inorganic layer U1 with the pixel opening SOP interposed between the first mask shadow MS1 and the first protrusion P1. The second mask shadow MS2 may be spaced apart from the second protrusion P2 of the second upper inorganic layer U2 with the pixel opening SOP interposed between the second mask shadow MS2 and the second protrusion P2. Hereinafter, a description of the common structure between the mask MK1 and the mask MK3 will be omitted, and the differences between the mask MK1 and the mask MK3 will be described later.

The first mask shadow MS1 included in the mask MK3 may include a first surface m1a, a second surface m1b, and a first side surface m1c. The first side surface m1c of the first mask shadow MS1 may be an inclined surface.

In some embodiments, a width Wm1b of the second surface m1b of the first mask shadow MS1 in the first direction (X-axis direction) may be smaller than a width Wm1a of the first surface m1a of the first mask shadow MS1. In some aspects, a first inclination angle θ1 formed between the second surface m1b and the first side surface m1c of the first mask shadow MS1 may be an obtuse angle.

In a process of manufacturing the mask MK3, a portion of the first mask shadow MS1 may be removed by an etching process performed in a direction of the lower surface s2 of the mask substrate MSUB. Therefore, the first side surface m1c of the first mask shadow MS1 may be an inclined surface, the width Wm1b of the second surface m1b may be smaller than the width Wm1a of the first surface m1a, and the first inclination angle θ1 may be the obtuse angle.

The second mask shadow MS2 may be positioned on the first mask shadow MS1.

The second mask shadow MS2 included in the mask MK3 may include a third surface m2a, a fourth surface m2b, and a second side surface m2c.

In some embodiments, a width Wm2b of the fourth surface m2b of the second mask shadow MS2 included in the mask MK3 may be greater than a width Wm2a of the third surface m2a of the second mask shadow MS2. In some aspects, a second inclination angle θ2 formed between the third surface m2a and the second side surface m2c of the second mask shadow MS2 may be an obtuse angle.

In a process of manufacturing the mask MK3, a portion of the second mask shadow MS2 may be removed by an etching process performed in a direction of the upper surface s1 of the mask substrate MSUB. Therefore, the second side surface m2c of the second mask shadow MS2 may be an inclined surface, the width Wm2b of the fourth surface m2b may be greater than the width Wm2a of the third surface m2a, and the second inclination angle θ2 may be the obtuse angle. That is, a portion of the mask shadow MS included in the mask MK3 may be removed by an etching process performed on both sides in the third direction (Z-axis direction), and as a result, the mask shadow MS may be formed in the form illustrated in FIG. 12.

In other words, it may be seen in the mask MK3 that a portion of the first mask shadow MS1 is etched by the etching process performed in a rear direction of the mask substrate MSUB in the manufacturing process through the shapes of the first surface m1a, the second surface m1b, and the first side surface m1c of the first mask shadow MS1, and that a portion of the second mask shadow MS2 is etched by the etching process performed in a front direction of the mask substrate MSUB in the manufacturing process through the shapes of the third surface m2a, the fourth surface m2b, and the second side surface m2c of the second mask shadow MS2.

In some embodiments, a height Hms31 of the first mask shadow MS1 included in the mask MK3 may be lower than a height Hms32 of the second mask shadow MS2, but is not limited thereto.

The mask MK3 according to an embodiment may support adjustments the degree of bending of the mask shadow MS by forming the first mask shadow MS1 and the second mask shadow MS2 to have stresses of different physical properties. As a result, the mask MK3 according to an embodiment may have improved adhesion between the display panel (410 in FIG. 5) and the mask MK3 during the deposition process.

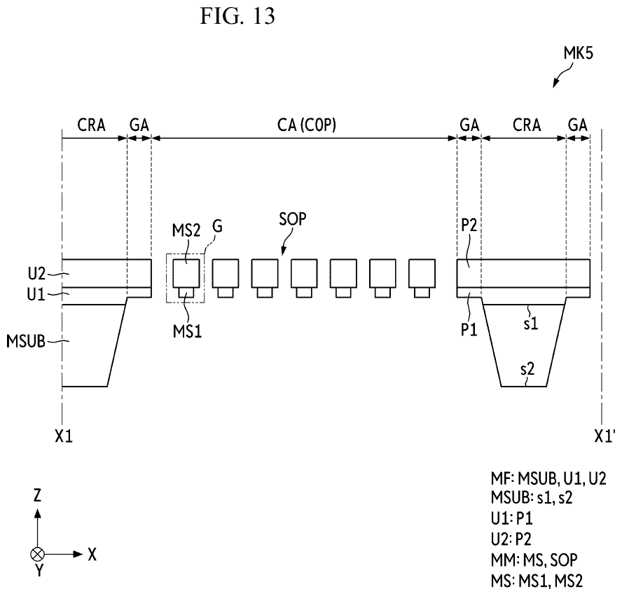

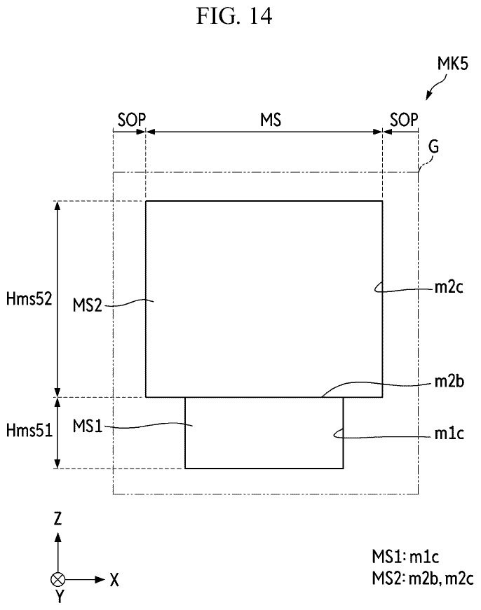

FIG. 13 is a cross-sectional view taken along line X1-X1′ of FIG. 6, as still another embodiment. FIG. 14 is an enlarged cross-sectional view of area G of FIG. 13.

Referring to FIGS. 13 and 14, a mask shadow MS included in a mask MK5 may have a different shape from the mask shadow MS included in the mask MK1.

The mask shadow MS included in the mask MK5 may include a first mask shadow MS1 and a second mask shadow MS2 that are stacked in the third direction (Z-axis direction). The first mask shadow MS1 may be spaced apart from the first protrusion P1 of the first upper inorganic layer U1 with the pixel opening SOP interposed between the first mask shadow MS1 and the first protrusion P1. The second mask shadow MS2 may be spaced apart from the second protrusion P2 of the second upper inorganic layer U2 with the pixel opening SOP interposed between the second mask shadow MS2 and the second protrusion P2. Hereinafter, a description of the common structure between the mask MK1 and the mask MK5 will be omitted, and the differences between the mask MK1 and the mask MK5 will be described later.

The first mask shadow MS1 included in the mask MK5 may include a first side surface m1c. The first side surface m1c of the first mask shadow MS1 may be an inclined surface, but is not limited thereto. In some aspects, the second mask shadow MS2 included in the mask MK5 may include a fourth surface m2b and a second side surface m2c. The second side surface m2c of the second mask shadow MS2 may be an inclined surface, but is not limited thereto.

The first side surface m1c of the first mask shadow MS1 included in the mask MK5 may be more depressed in the first direction (X-axis direction) than the second side surface m2c of the second mask shadow MS2. Therefore, an undercut may be formed between the fourth surface m2b of the second mask shadow MS2 and the first side surface m1c of the first mask shadow MS1.

In a process of manufacturing the mask MK5, the first mask shadow MS1 may be formed in the illustrated shape by an etching process performed in a direction of the lower surface s2 of the mask substrate MSUB. In some aspects, the second mask shadow MS2 may be formed in the illustrated shape by an etching process performed in a direction of the upper surface s1 of the mask substrate MSUB. That is, a portion of the mask shadow MS included in the mask MK5 may be removed by an etching process performed on both sides in the third direction (Z-axis direction), and as a result, the mask shadow MS may be formed in the form illustrated in FIG. 14.

As described herein, the first mask shadow MS1 and the second mask shadow MS2 may include different inorganic materials. Therefore, in the etching process included in the process of manufacturing the mask MK5, the first mask shadow MS1 and the second mask shadow MS2 may have different etching rates for the same etching solution. As an example, the first mask shadow MS1 may have a higher etching rate than the second mask shadow MS2 for the same etching solution. Therefore, an undercut may be formed between the second mask shadow MS2 and the first side surface m1c of the first mask shadow MS1.

In some embodiments, a height Hms51 of the first mask shadow MS1 included in the mask MK5 may be lower than a height Hms52 of the second mask shadow MS2, but is not limited thereto.

The mask MK5 may support adjustments to the degree of bending of the mask shadow MS by forming the first mask shadow MS1 and the second mask shadow MS2 to have stresses of different physical properties. As a result, the mask MK5 according to an embodiment may have improved adhesion between the display panel (410 in FIG. 5) and the mask MK5 during the deposition process.

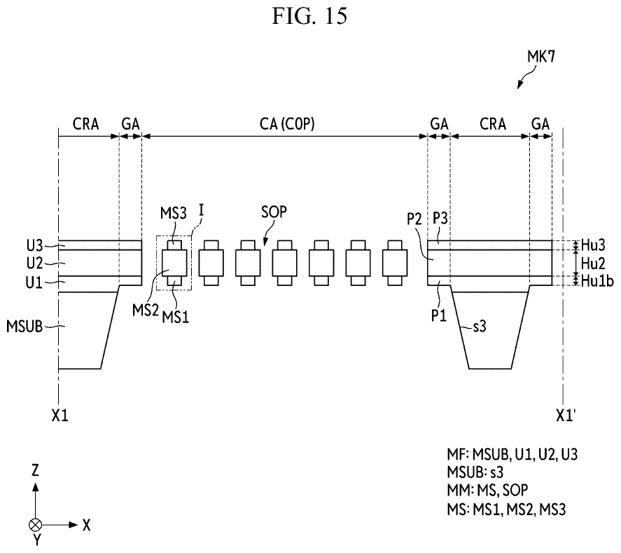

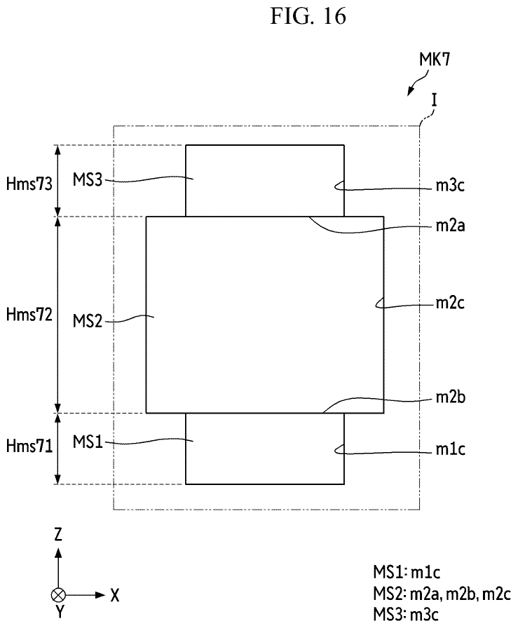

FIG. 15 is a cross-sectional view taken along line X1-X1′ of FIG. 6, as still another embodiment. FIG. 16 is an enlarged cross-sectional view of area I of FIG. 15.

Referring to FIGS. 15 and 16, a mask frame MF and a mask shadow MS included in a mask MK7 may have different shapes from the mask frame MF and mask shadow MS included in the mask MK1. Hereinafter, a description of the common structure between the mask MK1 and the mask MK7 will be omitted, and the differences between the mask MK1 and the mask MK7 will be described later.

The mask frame MF included in the mask MK7 may include a mask substrate MSUB, a first upper inorganic layer U1, a second upper inorganic layer U2, and a third upper inorganic layer U3. The third upper inorganic layer U3 may entirely cover the second upper inorganic layer U2 in a portion overlapping the cell peripheral area CRA. The third upper inorganic layer U3 may be formed to solve scratch defects in a display panel 410 caused by the mask MK7 when using the mask MK7.

The third upper inorganic layer U3 may include an inorganic insulating material. As an example, the third upper inorganic layer U3 may include any one of silicon oxide, silicon oxynitride, and silicon nitride.

The third upper inorganic layer U3 and the first upper inorganic layer U1 may

include the same material, and the third upper inorganic layer U3 may include a different material from the second upper inorganic layer U2. The mask MK7 may support adjusting stress applied to the mask MK7 by adjusting stress physical properties of the first upper inorganic layer U1, the second upper inorganic layer U2, and the third upper inorganic layer U3, respectively, stacked in the third direction (Z-axis direction).

The third upper inorganic layer U3 may include a third protrusion P3 in a portion overlapping the grid area GA. The third protrusion P3 may be a portion that protrudes more toward the cell area CA than the side surface s3 of the mask substrate MSUB. In the portion overlapping the grid area GA, the first protrusion P1 of the first upper inorganic layer U1, the second protrusion P2 of the second upper inorganic layer U2, and the third protrusion P3 of the third upper inorganic layer U3 may be sequentially stacked.

The mask shadow MS included in the mask MK7 may be spaced apart from the third protrusion P3 of the third upper inorganic layer U3 with the pixel opening SOP interposed between the mask shadow MS and the third protrusion P3.

The mask shadow MS included in the mask MK7 may include a first mask shadow MS1, a second mask shadow MS2, and a third mask shadow MS3 that are stacked in the third direction (Z-axis direction). The first upper inorganic layer U1 and the first mask shadow MS1 may include the same material, the second upper inorganic layer U2 and the second mask shadow MS2 may include the same material, and the third upper inorganic layer U3 and the third mask shadow MS3 may include the same material. The third mask shadow MS3 included in the mask MK7 may be spaced apart from the third protrusion P3 of the third upper inorganic layer U3 with the pixel opening SOP interposed between the third mask shadow MS3 and the third protrusion P3.

The first upper inorganic layer U1 and the first mask shadow MS1 may be formed integrally during a process of manufacturing the mask MK7, and then be spaced apart from each other in the form illustrated in FIG. 15 by a subsequent etching process, the second upper inorganic layer U2 and the second mask shadow MS2 may be formed integrally during the process of manufacturing the mask MK7, and then be spaced apart from each other in the form illustrated in FIG. 15 by a subsequent etching process, and the third upper inorganic layer U3 and the third mask shadow MS3 may be formed integrally during the process of manufacturing the mask MK7, and then be spaced apart from each other in the form illustrated in FIG. 15 by a subsequent etching process. Other redundant descriptions will be omitted.

In some embodiments, the first mask shadow MS1 included in the mask MK7 may include a first side surface m1c. The first side surface m1c of the first mask shadow MS1 may be an inclined surface, but is not limited thereto.

In some embodiments, the second mask shadow MS2 included in the mask MK7 may include a third surface m2a, a fourth surface m2b, and a second side surface m2c. The third surface m2a of the second mask shadow MS2 may be a surface facing the third mask shadow MS3, and the fourth surface m2b of the second mask shadow MS2 may be a surface facing the first mask shadow MS1. The third surface m2a and the fourth surface m2b may be positioned to be opposite to each other. The second side surface m2c may be a surface connecting the third surface m2a and the fourth surface m2b and may be an inclined surface, but is not limited thereto.

In some embodiments, the third mask shadow MS3 included in the mask MK7 may include a third side surface m3c. The third side surface m3c of the third mask shadow MS3 may be an inclined surface, but is not limited thereto.

The first side surface m1c of the first mask shadow MS1 included in the mask MK7 may be more depressed in the first direction (X-axis direction) than the second side surface m2c of the second mask shadow MS2. Therefore, an undercut may be formed between the fourth surface m2b of the second mask shadow MS2 and the first side surface m1c of the first mask shadow MS1. In some aspects, the third side surface m3c of the third mask shadow MS3 may be more depressed in the first direction (X-axis direction) than the second side surface m2c of the second mask shadow MS2.

In a process of manufacturing the mask MK7, the mask shadow MS may include at least one of a process of etching the mask shadow MS in a direction of the lower surface s2 of the mask substrate MSUB and a process of etching the mask shadow MS in a direction of the upper surface s1 of the mask substrate MSUB.

As described herein, the first mask shadow MS1 and the third mask shadow MS3 may include the same inorganic material, and the second mask shadow MS2 may include an inorganic material different from the first mask shadow MS1 and the third mask shadow MS3. Therefore, the second mask shadow MS2 included in the mask MK7 may have an etching rate different from the first mask shadow MS1 and the third mask shadow MS3. As an example, the second mask shadow MS2 may have a higher etching rate than the first mask shadow MS1 and the third mask shadow MS3. Therefore, the first side m1c of the first mask shadow MS1 may be more depressed in the first direction (X-axis direction) than the second side surface m2c of the second mask shadow MS2, and the third side surface m3c of the third mask shadow MS3 may be more depressed in the first direction (X-axis direction) than the second side surface m2c of the second mask shadow MS2.

In some embodiments, a height Hms71 of the first mask shadow MS1 included in the mask MK7 may be lower than a height Hms72 of the second mask shadow MS2, and a height Hms73 of the third mask shadow MS3 may be lower than the height Hms72 of the second mask shadow MS2, but embodiments of the present disclosure are not limited thereto.

The mask MK7 according to an embodiment may support adjustments to the degree of bending of the mask shadow MS by forming the first mask shadow MS1 and the second mask shadow MS2 to have stresses of different physical properties. As a result, the mask MK7 according to an embodiment may have improved adhesion between the display panel (410 in FIG. 5) and the mask MK7 during the deposition process. In some aspects, the mask MK7 according to an embodiment may solve scratch defects that occur in the display panel 410 when using the mask MK7 by including the third mask shadow MS3 including the same material as the first mask shadow MS1 on the second mask shadow MS2.

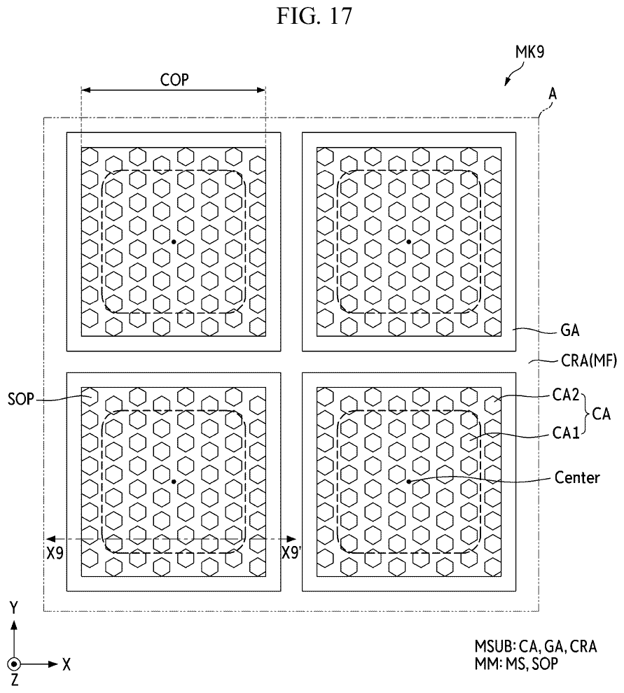

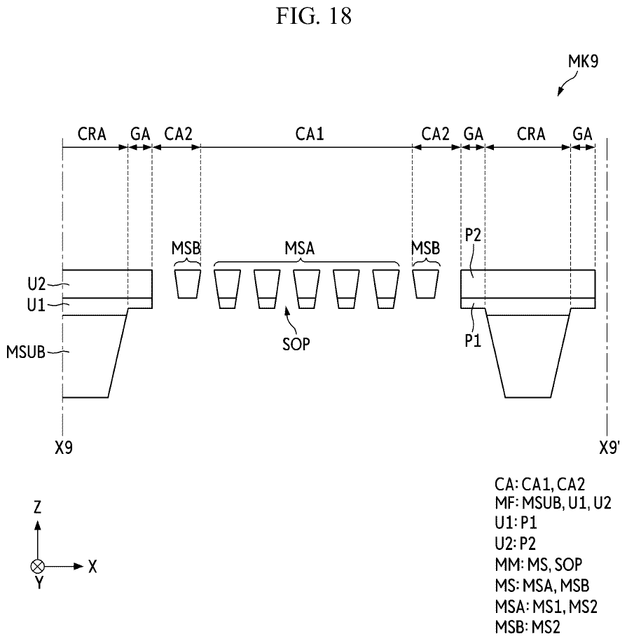

FIG. 17 is an enlarged plan view of area A of FIG. 6, as still another embodiment. FIG. 18 is a cross-sectional view taken along line X9-X9′ of FIG. 17.

Referring to FIG. 17, a cell area CA of a mask substrate MSUB included in a mask MK9 includes a first cell area CA1 and a second cell area CA2, which is different from the mask substrate MSUB included in the mask MK1. Hereinafter, a description of the common structure between the mask MK1 and the mask MK9 will be omitted, and the differences between the mask MK1 and the mask MK9 will be described later.

In a plan view, the cell area CA included in the mask MK9 may include a first cell area CA1 and a second cell area CA2. The first cell area CA1 may be an area including the center of the cell area CA (or an area forming the center of the cell area CA), and the second cell area CA2 may be the remaining area of the cell area CA excluding the first cell area CA1.

In a plan view, the first cell area CAL included in the mask MK9 may be positioned to be completely surrounded by the second cell area CA2, and the second cell area CA2 may be positioned to be completely surrounded by the grid area GA. Other redundant descriptions will be omitted.

Referring to FIGS. 17 and 18, a mask frame MF included in the mask MK9 may include a mask substrate MSUB, a first upper inorganic layer U1, and a second upper inorganic layer U2 in a portion overlapping the cell peripheral area CRA. In some aspects, a first protrusion P1 of the first upper inorganic layer U1 and a second protrusion P2 of the second upper inorganic layer U2 included in the mask MK9 may be stacked in the third direction (Z-axis direction) in a portion overlapping the grid area GA.

A mask membrane MM included in the mask MK9 may be positioned in a portion overlapping the cell area CA, and may include a mask shadow MS and a pixel opening SOP. The mask shadow MS may be positioned to surround the pixel opening SOP. Other redundant descriptions will be omitted.

The mask shadow MS included in the mask MK9 may include a first portion MSA and a second portion MSB. The first portion MSA may be positioned in a portion overlapping the first cell area CA1, and the second portion MSB may be positioned in a portion overlapping the second cell area CA2.

In some embodiments, the first portion MSA of the mask shadow MS may include a first mask shadow MS1 and a second mask shadow MS2. The first portion MSA of the mask shadow MS may have the same structure and characteristics as the mask shadow MS of the mask MK1 described herein. That is, the first mask shadow MS1 and the second mask shadow MS2 included in the mask MK9 may include different inorganic materials, and may include different stress physical properties.

In a process of manufacturing the mask MK9, the first mask shadow MS1 may be formed in the illustrated shape by an etching process performed in a direction of the lower surface s2 of the mask substrate MSUB. In some aspects, the second mask shadow MS2 may be formed in the illustrated shape by at least one of an etching process performed in a direction of the upper surface s1 of the mask substrate MSUB or an etching process performed in a direction of the lower surface s2 of the mask substrate MSUB.

It is illustrated in FIG. 18 that the first portion MSA of the mask shadow MS has an inverse tapered shape, but embodiments of the present disclosure are not limited thereto. Depending on the embodiment, the first portion MSA of the mask shadow MS included in the mask MK9 may have various shapes.

The second portion MSB of the mask shadow MS may include a second mask shadow MS2 in a portion overlapping the second cell area CA2. The second portion MSB of the mask shadow MS may not include the first mask shadow MS1.

In the process of manufacturing the mask MK9, the mask shadow MS may be formed to include a first mask shadow MS1 and a second mask shadow MS2 that are stacked in the third direction (Z-axis direction) in portions overlapping the first cell area CA1 and the second cell area CA2. However, the first mask shadow MS1 positioned in a portion overlapping the second cell area CA2 may be removed through a subsequent etching process, and as a result, the mask shadow MS may be divided into the first portion MSA and the second portion MSB including different structures.

The mask MK9 may support finely controlling a stress of the mask shadow MS by forming structures of the mask shadow MS positioned to overlap each of the first cell area CA1 and the second cell area CA2 to be different from each other. In other words, the mask MK9 may support finely controlling the stress formed in the mask shadow MS by forming the structures of the mask shadow MS overlapping in the same cell area CA to be different from each other.

The mask MK9 may support adjustments to the degree of bending of the mask shadow MS by forming the first mask shadow MS1 and the second mask shadow MS2 to have stresses of different physical properties. As a result, the mask MK9 may have improved adhesion between the display panel (410 in FIG. 5) and the mask MK9 during the deposition process.

In some aspects, the mask MK9 may support finely controlling the stress formed in the mask shadow MS by forming the first portion MSA and the second portion MSB of the mask shadow MS to have different stresses.

The invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate comprising a cell area and a cell peripheral area;
a mask membrane positioned in the cell area of the mask substrate and comprising a pixel opening and a mask shadow surrounding the pixel opening;
a first upper inorganic layer positioned on the cell peripheral area of the mask substrate and comprising a first protrusion that protrudes more toward the cell area than a side surface of the mask substrate; and
a second upper inorganic layer positioned on the first upper inorganic layer and comprising a second protrusion that protrudes more toward the cell area than the side surface of the mask substrate,
wherein the mask shadow comprises:
a first mask shadow spaced apart from the first protrusion with the pixel opening interposed between the first mask shadow and the first protrusion, wherein the first mask shadow and the first upper inorganic layer comprise a same material; and
a second mask shadow spaced apart from the second protrusion with the pixel opening interposed between the second mask shadow and the second protrusion, wherein the second mask shadow and the second upper inorganic layer comprise a same material, and
the first mask shadow and the second mask shadow respectively comprise different materials.

2. The deposition mask of claim 1, wherein:
the first mask shadow comprises silicon oxide, and
the second mask shadow comprises silicon nitride.

3. The deposition mask of claim 2, wherein a height of the second protrusion in a direction perpendicular to the mask substrate is equal to a height of the second mask shadow.

4. The deposition mask of claim 2, wherein a height of the first protrusion in a direction perpendicular to the mask substrate is equal to a height of the first mask shadow.

5. The deposition mask of claim 2, wherein:
the first mask shadow comprises a first surface facing the second mask shadow and a second surface opposite the first surface, and
the second mask shadow comprises a third surface facing away from the first mask shadow and a fourth surface opposite the third surface.

6. The deposition mask of claim 5, wherein:
a width of the first surface in a direction parallel to the mask substrate is greater than a width of the second surface, and
a width of the third surface is greater than a width of the fourth surface.

7. The deposition mask of claim 6, wherein the mask shadow has an inverse tapered shape.

8. The deposition mask of claim 5, wherein:
the first mask shadow further comprises a first side surface connecting the first surface and the second surface, and
the second mask shadow further comprises a second side surface connecting the third surface and the fourth surface.

9. The deposition mask of claim 8, wherein:
a width of the first surface in a direction parallel to the mask substrate is greater than a width of the second surface, and
a width of the third surface is smaller than a width of the fourth surface.

10. The deposition mask of claim 9, wherein:
a first inclination angle formed between the second surface and the first side surface of the first mask shadow is an obtuse angle; and
a second inclination angle formed between the third surface and the second side surface of the second mask shadow is an obtuse angle.

11. The deposition mask of claim 8, wherein the second side surface protrudes more toward the pixel opening than the first side surface.

12. The deposition mask of claim 9, wherein an undercut is formed between the fourth surface and the first side surface.

13. The deposition mask of claim 2, further comprising a third upper inorganic layer positioned on the second upper inorganic layer and comprising a third protrusion that protrudes more toward the cell area than the side surface of the mask substrate,
wherein the third upper inorganic layer and the first upper inorganic layer comprise a same material.

14. The deposition mask of claim 13, wherein the mask shadow further comprises a third mask shadow spaced apart from the third protrusion with the pixel opening interposed between the third mask shadow and the third protrusion, wherein the third mask shadow and the third upper inorganic layer comprising a same material.

15. The deposition mask of claim 14, wherein a side surface of the second mask shadow facing the pixel opening protrudes more toward the pixel opening than a side surface of the third mask shadow facing the pixel opening.

16. The deposition mask of claim 2, wherein:
the cell area comprises a first cell area comprising a center of the cell area and a second cell area surrounding the first cell area,
a first portion of the mask shadow overlapping the first cell area comprises the first mask shadow and the second mask shadow, and
a second portion of the mask shadow overlapping the second cell area comprises the second mask shadow but does not comprise the first mask shadow.

17. The deposition mask of claim 16, wherein:
in a plan view, the first cell area is completely surrounded by the second cell area, and
in the plan view, the second cell area is completely surrounded by the cell peripheral area.

18. The deposition mask of claim 1, further comprising a grid area positioned between the cell area and the cell peripheral area,
wherein:
the first protrusion and the second protrusion are sequentially stacked in a direction perpendicular to the mask substrate in a portion overlapping the grid area, and
the mask substrate, the first upper inorganic layer, the second upper inorganic layer, and the mask membrane do not overlap the grid area.

19. The deposition mask of claim 18, wherein:
in a plan view, the cell area is completely surrounded by the grid area, and
in the plan view, the grid area is completely surrounded by the cell peripheral area.

20. The deposition mask of claim 1, wherein:
the mask substrate comprises silicon, and
the mask substrate has a circular shape in a plan view.

21. An electronic device comprising:
a display device formed using a deposition mask;
the deposition mask comprising: a mask substrate comprising a cell area and a cell peripheral area;
a mask membrane positioned in the cell area of the mask substrate and comprising a pixel opening and a mask shadow surrounding the pixel opening;
a first upper inorganic layer positioned on the cell peripheral area of the mask substrate and comprising a first protrusion that protrudes more toward the cell area than a side surface of the mask substrate; and
a second upper inorganic layer positioned on the first upper inorganic layer and comprising a second protrusion that protrudes more toward the cell area than the side surface of the mask substrate,
wherein the mask shadow comprises:
a first mask shadow spaced apart from the first protrusion with the pixel opening interposed between the first mask shadow and the first protrusion, wherein the first mask shadow and the first upper inorganic layer comprise a same material; and
a second mask shadow spaced apart from the second protrusion with the pixel opening interposed between the second mask shadow and the second protrusion, wherein the second mask shadow and the second upper inorganic layer comprise a same material, and
the first mask shadow and the second mask shadow respectively comprise different materials.
